(19) United States
(12) Patent Application Publication
(10) Pub. No.: US 2008/0257584 A1
(43) Pub. Date: Oct. 23, 2008

(54) Multilayer wiring board

(75) Inventors: Akira Wada, Kariya-city (JP); Toshihisa Nakano, Kariya-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/900,428

(22) Filed: Sep. 12, 2007

(30) Foreign Application Priority Data
Sep. 14, 2006 (JP) 2006-249764

(51) Int. Cl. H05K 1/02

(52) U.S. Cl. 174/250

(57) ABSTRACT

A multilayer wiring board includes a substrate and even numbered wiring patterns. The substrate is made of an insulating material. Each of the even numbered wiring patterns is made of a conductive material, and the wiring patterns are laminated onto one another in a lamination direction via the substrate. One of the wiring patterns has a generally equivalent volume to that of a corresponding one of the wiring patterns. Here, the one of the wiring patterns is located on one plane symmetrical to a corresponding plane, on which the corresponding one of the wiring patterns is located, relative to a central position of the wiring patterns in the lamination direction.

### CROSS REFERENCE TO RELATED APPLICATION

This application is based on and incorporates herein by reference Japanese Patent Application No. 2006-249764 filed on Sep. 14, 2006.

### BACKGROUND OF THE INVENTION

1. Field of the Invention

The present invention relates to a multilayer wiring board having wiring patterns, which are laminated onto one another via a substrate made of an insulating material.

2. Description of Related Art

Conventionally, JP-A-10-215042 has disclosed a multilayer wiring board, in which warp is controlled. JP-A-10-215042 discloses a multilayer wiring board, in which multiple resin insulating layers and multiple thin film wiring conductor layers are alternately laminated onto one another on a insulating board. The thin film wiring conductor layers are electrically connected with each other via through-hole conductors formed in the corresponding resin insulating layers. A bonding pad is provided in an upper surface of a top layer of the resin insulating layers. Typically, the bonding pad is electrically connected with the thin film wiring conductor layer, and with external electronic parts. Also, a metallic layer is embedded almost entirely inside the insulating board to extend generally in parallel with a main surface of the insulating board in order to limit the warp of the multilayer wiring board.

However, the multilayer wiring board disclosed in JP-A-10-215042 disadvantageously requires the metallic layer for controlling (limiting) the warp, and thereby this increases a cost.

### SUMMARY OF THE INVENTION

The present invention is made in view of the above disadvantages. Thus, it is an objective of the present invention to address at least one of the above disadvantages.

To achieve the objective of the present invention, there is provided a multilayer wiring board, which includes a substrate and even numbered wiring patterns. The substrate is made of an insulating material. Each of the even numbered wiring patterns is made of a conductive material, and the wiring patterns are laminated onto one another in a lamination direction via the substrate. One of the wiring patterns has a generally equivalent volume to that of a corresponding one of the wiring patterns. Here, the one of the wiring patterns is located on one plane symmetrical to a corresponding plane, on which the corresponding one of the wiring patterns is located, relative to a central position of the wiring patterns in the lamination direction.

### BRIEF DESCRIPTION OF THE DRAWINGS

The invention, together with additional objectives, features and advantages thereof, will be best understood from the following description, the appended claims and the accompanying drawings in which:

FIG. 1 is a partial sectional view showing a schematic structure of a multilayer wiring board according to one embodiment of the present invention;

FIG. 2 is an exploded view showing a schematic structure of the multilayer wiring board according to the one embodiment of the present invention;

FIG. 3 is a top view showing a schematic structure of the multilayer wiring board according to the one embodiment of the present invention; and

FIG. 4 is a top view for explaining a volume adjustment of a wiring pattern according to the one embodiment of the present invention.

### DETAILED DESCRIPTION OF PREFERRED EMBODIMENTS

Hereafter, one embodiment of the present invention is described referring to accompanying drawings.

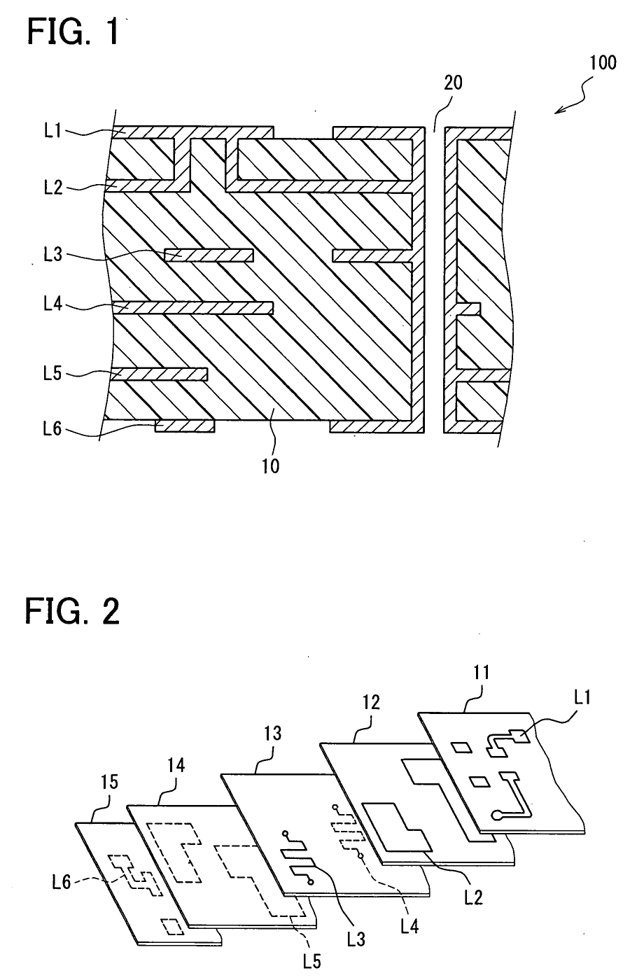

As shown in FIG. 1, a multilayer wiring board 100 of the present embodiment includes six layers of wiring patterns L1-L6 laminated onto one another via a resin substrate 10. Typically, the six layers of the wiring patterns L1-L6 are electrically connected with each other via a plated through hole 20.

As shown in FIG. 2, a resin boards 11-15, in which the wiring patterns L1-L6 are formed, are laminated onto one another and adhered to each other to form the resin substrate 10. For example, the resin boards 11-15 are insulating (dielectric) resin boards, which are made by impregnating reinforcement substrates, such as a glass cloth, with an insulating resin, such as an epoxy resin, in order to maintain the strength of the multilayer wiring board 100. In other words, the resin boards 11-15 are prepregs. In the present embodiment, the glass cloth impregnated with the epoxy resin serves as an example to describe each resin board 11-15. However, the present invention is not limited to this, and may, for example, employ a thermoplastic resin film, ceramics, and the like, for an alternative resin board.

The wiring patterns L1-L6 are made of a conductive material, such as a copper, and serve as signal wires of the multilayer wiring board 100, as a power supply pattern, and as a ground pattern. Also, as shown in FIG. 2, one of the wiring patterns L1-L6 has a generally equivalent volume to that of a corresponding one of the wiring patterns L1-L6. Here, the one of the wiring patterns L1-L6 is located on a plane symmetrical to a corresponding plane, on which the corresponding one of the wiring patterns L1-L6 is located, relative to a central position of the wiring patterns L1-L6 in the lamination direction (i.e., a central position of the multilayer wiring board 100 in the lamination direction). In this specification, a pair of the one of the wiring patterns L1-L6 and the corresponding one of the wiring patterns L1-L6 is named as a symmetrical pair of the wiring patterns L1-L6. Typically, the one of the wiring patterns L1-L6 is located on the plane symmetrical to the corresponding plane relative to an imaginary central plane, which extends perpendicularly to the lamination direction, and which includes the central position of the multilayer wiring board 100. For example, in the present embodiment, the wiring patterns L1 and L6 have generally equivalent volumes to each other, the wiring patterns L2 and L5 have generally equivalent volumes to each other, and the wiring patterns L3 and L4 have generally equivalent volumes to each other.

Also, a thickness across entire of each of the wiring patterns L1-L6 is generally the same with each other. Therefore, the one of the wiring patterns L1-L6 has a generally equivalent area to that of the corresponding one of the wiring patterns L1-L6. For example, the wiring patterns L1 and L6 have generally equivalent areas to each other. This is true for a pair of the wiring patterns L2 and L5, and to a pair of the wiring patterns L3 and L4.

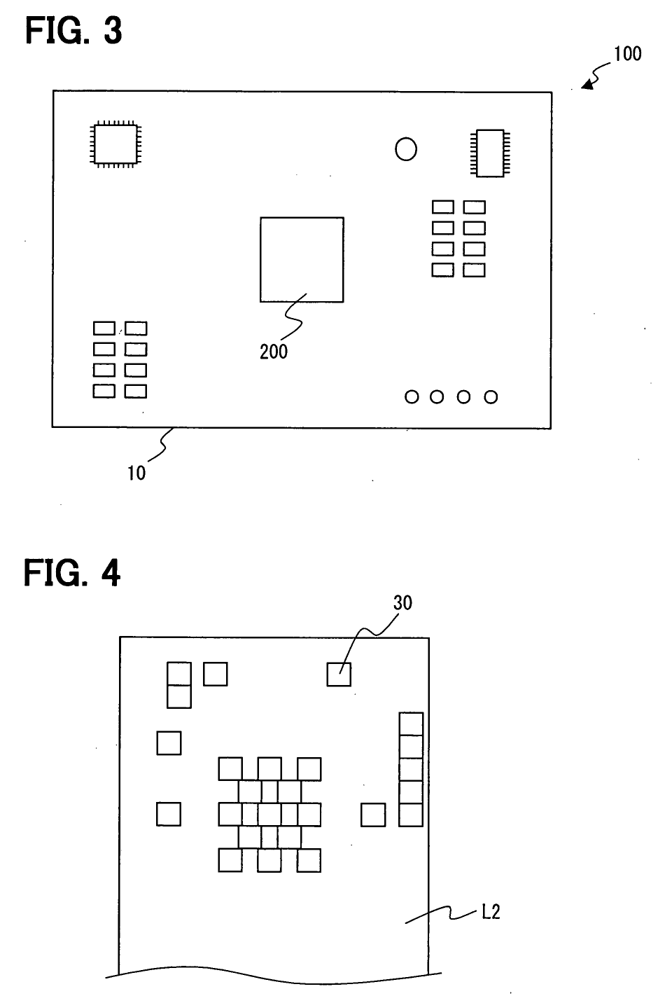

The above multilayer wiring boards 100 is mounted with two or more electronic parts, such as a BGA (ball grid array) chip 200 as shown in FIG. 3. The multilayer wiring board 100, in which the electronic parts are mounted, serves as an on-board image-processing ECU (Electric Control Unit), an engine ECU, and the like.

Here, a manufacturing method of the multilayer wiring board 100 of the present embodiment is explained. Firstly, conductive materials, which is to form the wiring patterns L1-L6, are provided on the corresponding surfaces of the resin boards 11-15. Next, the conductive materials formed on the resin boards 11-15 are suitably patterned by, for example, etching to form the wiring patterns L1-L6.

In this patterning process, the conductive materials are patterned such that the wiring pattern L1 has the generally equivalent volume to that of the wiring pattern L6, which is located on a plane symmetrical to a corresponding plane, on which the wiring pattern L1 is located, relative to the central position of the wiring patterns L1-L6 in the lamination direction. Similarly, the conductive materials are patterned such that the wiring pattern L2 has the generally equivalent volume to that of the wiring pattern L5, which is located on another plane symmetrical to another corresponding plane, on which the wiring pattern L2 is located, relative to the central position of the wiring patterns L1-L6 in the lamination direction. Also, the conductive materials are patterned such that the wiring pattern L3 has the generally equivalent volume to that of the wiring pattern L4, which is located on another plane symmetrical to another corresponding plane, on which the wiring pattern L3 is located, relative to the central position of the wiring patterns L1-L6 in the lamination direction. Thus, the plane is located symmetrical to the corresponding plane relative to the central position of the wiring patterns L1-L6 in the lamination direction.

When the conductive materials are patterned, the conductive materials are patterned according to the use of each of the wiring patterns L1-L6. In other words, in a case for making a wiring pattern for a mounting layer (for example, a wiring pattern L1 of a surface layer), which is mounted with electronic parts, the conductive material is patterned such that the conductive material becomes a comparatively thin signal wire, which connects between lands for mounting the electronic parts. Also, in another case for making a wiring pattern for another layer (for example, wiring patterns L2, L5), which forms a power supply pattern and a ground pattern, the conductive material is patterned such that the conductive material becomes a solid pattern with a comparatively large area.

Then, as above, the conductive materials are cut (for example, part of the conductive material is removed) for adjustment of the volume of each wiring pattern L1-L6 such that one of the symmetrical pair of the wiring patterns L1-L6 has the generally equivalent volume to the other. In this case, the conductive material is cut so that the removed conductive material segment, which is cut and removed from the conductive material, has a predetermined volume. In other words, as shown in FIG. 4, the conductive material is cut such that a removed conductive material segment (not shown) has a shape of a square of 1 mm×1 mm, and thereby the conductive material has a volume adjustment portion 30 having an empty volume that corresponds to the predetermined volume. For example, the volume adjustment portion 30 is a hole, which is formed in the conductive material, and which has the predetermined volume. Thus, the volume adjustment portions 30 are formed so that each of the wiring patterns L1-L6 has the respective target volume.

As above, the volume adjustment portions 30 each having the predetermined volume are cut and removed from each conductive material to adjust the volume of each of the wiring patterns L1-L6. Thus, the volume of each of the wiring patterns L1-L6 can be computed easily.

The shape of the volume adjustment portion 30 is not limited to a square column, but may be a cylindrical column and a triangular column. Furthermore, the size and the shape of the volume adjustment portion 30 is not limited to the square of 1 mm×1 mm.

When the volume adjustment portions 30 having the predetermined volume are formed as above to adjust the volume of each of the wiring patterns L1-L6, it is desirable that the volume adjustment portions 30 are generally uniformly (equally) provided to the corresponding wiring pattern. For example, when adjusting the volume of the wiring pattern L1, the volume adjustment portions 30 are uniformly (evenly) provided to the entire wiring pattern L1 such that the volume adjustment portions 30 are not biased to, for example, one side or one part of the wiring pattern L1.

Next, the resin boards 11-15, which are formed with the wiring patterns L1-L6 as above, are laminated onto one another. Then, the laminated resin boards 11-15 are heated and compressed under vacuum to be bonded (adhered). In this way, the resin boards 11-15 are bonded to be a unit, and form the resin substrate 10.

Then, a through hole is formed in the resin substrate 10, which is made by lamination and bonding The plated through hole 20, which is an interlayer connection member, is formed by providing copper plating to the above through hole, and the plated through hole 20 provides electrical connection among the wiring patterns L1-L6. The electrical connection among the wiring patterns L1-L6 is not limited to the plated through hole 20. However, an alternative connection, such as a via hole, may be provided to each of the resin boards 11-15 for electrical connection.

Further, the Electronic parts, such as the BGA chip 200, are mounted in the multilayer wiring board 100 formed as above. In this case, a reflow process is performed in a state, where the electronic parts are mounted on the lands that are electrically connected to the wiring pattern L1 or the wiring pattern L6 of the multilayer wiring board 100. For example, the reflow process is performed after solder balls, which are terminals of the BGA chip 200, have contacted with the lands such that the BGA chip 200 is mounted in the multilayer wiring board 100.

As above, the one of the wiring patterns L1-L6 has the generally equivalent volume to that of the corresponding one of the wiring patterns L1-L6. Here, the one of the wiring patterns L1-L6 is located on the plane symmetrical to the corresponding plane, on which the corresponding one of the wiring patterns L1-L6 is located, relative to the central position of the wiring patterns L1-L6 in the lamination direction. Therefore, the internal stress (stress, which acts on the wiring patterns L1-L6 and the substrate 10) caused by a difference between (a) linear expansion of the insulating material, which constitutes the resin substrate 10, and (b) linear expansion of the conductive material, which constitutes the wiring patterns L1-L6, can be equally distributed in the entire of the multilayer wiring board 100. Therefore, warp of the multilayer wiring board 100 can be controlled (limited).

Typically, the connection examination of the BGA chip 200 may be difficult to be performed after the BGA chip 200 has been mounted because of its shape. Therefore, because the multilayer wiring board 100 of the present invention can control the warp, the multilayer wiring board 100 is typically employed as a multilayer wiring board for mounting the BGA chip 200. Also, because the multilayer wiring board 100 of the present embodiment can control the warp, the multilayer wiring board 100 can be surely mounted with a comparatively large-sized BGA chip 200 without degrading reliability.

Also because the multilayer wiring board 100 of the present embodiment can control the warp, the BGA chip 200 can be mounted in a central part of one surface of the multilayer wiring board 100 as shown in FIG. 3, without reducing the connection reliability. That is, when the present invention is applied to the multilayer wiring board mounted with a BGA chip in the central part of one surface thereof, the connection reliability between the BGA chip and the multilayer wiring board can be limited from degrading.

Also, it is typical that each of the wiring patterns L1-L6 has the generally similar thickness to each other. However, in order to improve heat dissipation property, or in order to provide more current, the thickness can be partially enlarged (e.g., thickness of one wiring pattern of one layer may be enlarged). In such a case, a thickness of a corresponding wiring pattern corresponding to the wiring pattern, whose thickness is enlarged, is also enlarged for volume adjustment. Alternatively, the corresponding wiring pattern may have a larger area for volume adjustment.

The warp of the multilayer wiring board 100 may be produced at the time of the bonding process for bonding the resin boards 11-15 together or at the time of the reflow process for mounting the electronic parts. In the manufacturing process, such as the bonding process and the reflow process, the multilayer wiring board 100 includes a handle part formed in the periphery thereof. Typically, the handle part is adapted to be held by a conveying equipment etc. When the manufacturing process ends, the handle part is detached. In other words, the multilayer wiring board 100 shown in FIG. 1 and the like is a product part of the multilayer wiring board 100.

Therefore, in order that the symmetrical pair of the wiring patterns L1-L6 have the generally equal volumes to each other, the symmetrical pair of the wiring patterns L1-L6 may be formed to have the generally equivalent volumes in a state, where the multilayer wiring board 100 has the product part and the handle part. As a result, the warp of the multilayer wiring board 100 can be further reduced.

Also, the resin substrate 10 includes non wiring pattern portions, in which the wiring patterns L1-L6 are not formed, and one of the wiring patterns L1-L6 and a corresponding one of the non wiring pattern portions may be generally uniformly provided in each layer. Due to the above, internal stress (stress, which acts on the wiring pattern and the substrate) caused by a difference between (a) linear expansion of the insulating material, which constitutes the resin substrate 10, and (b) linear expansion of the conductive material, which constitutes the wiring patterns L1-L6, can be uniformly (equally) distributed also in each layer. Therefore, the warp of the multilayer wiring board 100 can be controlled further. For example, in the present embodiment, the layer indicates a plane (e.g., one plane), on which the one of the wiring patterns L1-L6 is located. Also, the corresponding one of the non wiring pattern portions is located on the plane. Thus, for example, the wiring pattern L2 and the non wiring pattern portion of the resin substrate 10 corresponding to the wiring pattern L2 are located on one layer (plane), and the wiring pattern L2 and the non wiring pattern portion are uniformly (evenly) provided to the one layer.

The above symmetrical pair of the wiring patterns L1-L6 is formed to have the generally equivalent volumes to each other, and may also be located symmetrical to each other relative to the central position of the wiring patterns L1-L6 in the lamination direction. For example, the central position of the wiring patterns L1-L6 may be a center of gravity of the multilayer wiring board 100 or a center of the multilayer wiring board 100 in the lamination direction. Therefore, the internal stress (stress, which acts on the wiring patterns L1-L6 and the substrate 10) caused by a difference between (a) linear expansion of the insulating material, which constitutes the resin substrate 10, and (b) linear expansion of the conductive material, which constitutes the wiring patterns L1-L6, can be equally distributed between the symmetrical pair of the wiring patterns. Therefore, the warp of the multilayer wiring board 100 can be controlled (limited).

In the present embodiment, the multilayer wiring board 100 of the six layers is explained as an example. However, the present invention is not limited to the multilayer wiring board 100 of the six layers. The multilayer wiring board may be a multilayer wiring board having even-numbered layers of wiring patterns other than six layers. In other words, an alternative multilayer wiring board may have wiring patterns, the number of which is even other than six.

Additional advantages and modifications will readily occur to those skilled in the art. The invention in its broader terms is therefore not limited to the specific details, representative apparatus, and illustrative examples shown and described.

What is claimed is:

1. A multilayer wiring board comprising:
a substrate that is made of an insulating material; and
even numbered wiring patterns, each of which is made of a conductive material, the wiring patterns being laminated onto one another in a lamination direction via the substrate, wherein:
one of the wiring patterns has a generally equivalent volume to that of a corresponding one of the wiring patterns, the one of the wiring patterns being located on one plane symmetrical to a corresponding plane, on which the corresponding one of the wiring patterns is located, relative to a central position of the wiring patterns in the lamination direction.

2. The multilayer wiring board according to claim 1, wherein:
the substrate includes non wiring pattern portions, in which the wiring patterns are prevented from being formed; and
the one of the wiring patterns and a corresponding one of the non wiring pattern portions are generally uniformly provided.

3. The multilayer wiring board according to claim 1, wherein the one of the wiring patterns has a volume adjustment portion, which has a removed portion having a predetermined volume.

4. The multilayer wiring board according to claim 1, wherein the one of the wiring patterns is located generally symmetrical to the corresponding one of the wiring patterns relative to the central position of the wiring patterns in the lamination direction.

5. The multilayer wiring board according to claim 2, wherein the corresponding one of the non wiring pattern portions is located on the one plane.

6. The multilayer wiring board according to claim 1, wherein the one of the wiring patterns has a volume adjustment portion, which is a hole having a predetermined volume.

7. The multilayer wiring board according to claim 6, wherein the volume adjustment portion is one of a plurality of volume adjustment portions, which are generally uniformly provided to the one of the wiring patterns.

8. The multilayer wiring board according to claim 1, wherein the one plane is symmetrical to the corresponding plane relative to an imaginary plane, which extends perpendicularly to the lamination direction, and which includes the central position of the wiring patterns in the lamination direction.
